(19) United States
(12) Patent Application Publication
(10) Pub. No.: US 2015/0066414 A1
(43) Pub. Date: Mar. 5, 2015

(54) AUTOMATIC RETEST METHOD FOR SYSTEM-LEVEL IC TEST EQUIPMENT AND IC TEST EQUIPMENT USING SAME

(71) Applicant: CHROMA ATE INC., Kuei-Shan Hsiang (TW)

(72) Inventors: Chin-Yi Ouyang, Kuei-Shan Hsiang (TW); Liang-Yu Hsu, Kuei-Shan Hsiang (TW)

(73) Assignee: CHROMA ATE INC., Kuei-Shan Hsiang (TW)

(21) Appl. No.: 14/261,427

(22) Filed: Apr. 25, 2014

(30) Foreign Application Priority Data
Aug. 30, 2013 (TW) 102131279

(51) Int. Cl. G01R 31/28

(52) U.S. Cl. CPC G01R 31/2894
USPC 702/117

(57) ABSTRACT

An automatic retest method for a system-level IC test equipment and the IC test equipment is disclosed, wherein the IC test equipment includes multiple testing units, a loading/unloading unit, and a processing unit; each testing unit is capable of testing an IC individually and has a pass rate. When the testing unit finishes a test operation, it will send test report of the IC to the processing unit. The processing unit will determine whether the IC has reached a pass threshold of the testing unit. The processing unit will issue a command, according to a predetermined rule, to transfer the IC that failed to reach the pass threshold to one of the testing units conforming to the predetermined rule to conduct a retest operation. Finally, the processing unit will confirm whether the IC that failed to reach the pass threshold has reached the pass threshold in the retest operation.

### FIELD OF THE INVENTION

The present invention relates to a system-level IC test equipment and, more particularly, to an automatic retest method for a system-level IC test equipment and the IC test equipment using the same.

### BACKGROUND OF THE INVENTION

With the rapid development of semiconductor technology, the IC chips are becoming to have more complicated structures. In fabricating electronic products, a mechanical or automatic way of mounting electronic components onto PCBs (printed circuit boards) has been used extensively to replace the conventional manual way. A full automatic process is involved with IC (integrated circuit) fabrication, IC inspection, IC sorting, mounting and soldering IC chips onto PCBs, and final product inspection. The purpose of employing the automatic process is to effectively eliminate the defect components in a shorter time to ensure the quality of the final product. Therefore, the stability and accuracy of the test machine is a key element in developing semiconductor technology. In a process of fabricating a semiconductor chip, such as a CPU or graphics chip, there are various stages needed to be tested. Firstly, after the semiconductor chip is fabricated, the chip's appearance will be inspected, and then specific contacts or pins of the chip will be tested to ensure that they perform as expected. This type of test is known as a simulation test.

Next, the execution speed of the semiconductor chip will be evaluated. Usually, the semiconductor chip is temporarily mounted, according to a test procedure, onto a functional circuit board, which is commonly known as a universal test board, and then a series of performance tests is automatically carried out on the semiconductor chip. For example, a graphics chip can be mounted to a video card connected to a mother board, whereby the mother board may either read the performance parameters of the chip or drive the video card to transmit signals to a monitor to display a test result, so as to assess the performance of the chip. This way of testing semiconductor chip by using a universal test board is commonly known as a real-world test.

After the above test is completed, the semiconductor chips having an unsatisfactory performance are usually deemed as failed devices and should be weeded out. Nevertheless, the failed semiconductor chips have passed basic tests and shown to meet basic requirements for performance. The failed semiconductor chips might only have a lower responsive speed during the test. Alternatively, the failure of the semiconductor chips may be simply attributed to inferior electrical contacts or even slight impairment of the electronic components in the testing instruments. Thus, discarding those failed semiconductor chips results in an undesired economic loss, as there may be workable devices among the failed chips. To avoid this problem, an automatic test machine is usually provided with a special tray in the bin region for storing the failed semiconductor chips having a lower responsive speed during the test, and the failed semiconductor chips will be retested after the test for the current batch of the semiconductor chips is completed.

In the case where a workable semiconductor chip was mistakenly sorted into the failed category by a test machine having six testing units as one of the testing units has certain problems in its associated circuit board and is to be retested in the same test machine, it is quite possible that the workable chip is going to be classified as a defect device again. As such, the problem of misclassifying a workable IC chip as a defect device in the test machine is still unavoidable.

On the other hand, some testing units may have a lower pass rate as they provide a higher threshold for passing the test. As such, semiconductor chips having an execution speed at the margin of passing the test will be simply weeded out. Nevertheless, a semiconductor chip being unable to pass at a testing unit may pass at another testing unit. For this reason, it is worthwhile to consider whether an IC failed in a retest operation is undoubtedly a defect device and how a reasonable test procedure should be carried out to ensure that an IC sorted as a defect device in the retest operation is truly a defect device. It is further worthwhile to determine whether an IC having a lower responsive speed can meet the requirements for a downgrade product that can still be sold in the market. Contrarily, when a higher standard for chips is required, it is worthwhile to consider whether a testing unit with a higher threshold can be selected to conduct a retest operation.

In view of the foregoing, the present invention focuses on developing a retest procedure that can conduct a retest operation more reasonably and objectively according to an operator's needs, and can avoid to mistakenly classify workable semiconductor chips as defect devices, so that the test results will be more accurate and the retest procedure can be performed more efficiently.

### SUMMARY OF THE INVENTION

An aspect of the present invention is to provide an automatic retest method for use in a system-level IC test equipment, which can arrange an IC required to be retested, according to an operator's needs, to a particular testing unit for increasing the efficiency of testing IC product.

Another aspect of the present invention is to provide an automatic retest method for use in a system-level IC test equipment, which can arrange an IC required to be retested to a testing unit having a greater pass rate, to avoid the possibility of mistakenly classifying a workable IC as a defect device.

A further aspect of the present invention is to provide an automatic retest method for use in a system-level IC test equipment, which can enhance the pass rate for a batch of IC chips under test, so that the IC product yield can be increased.

A still further aspect of the present invention is to provide an automatic system-level IC test equipment, which can arrange the ICs required to be retested to other testing units for obtaining a more objective test result.

A still further aspect of the present invention is to provide an automatic system-level IC test equipment, which can increase the efficiency of retesting IC chips.

To achieve the above aspects, the invention provides a method of testing IC chips for a system-level IC test equipment that includes a processing unit, a loading/unloading unit, and multiple testing units adapted for testing the IC chips independently, wherein each of the testing units provides a pass rate for IC chips, the method comprising the steps of:

(a) using the testing units to test the IC chips individually and transmitting a test result of the IC chips to the processing unit;

(b) using the processing unit to assess whether the respective IC chips have reached pass thresholds of the respective testing units, according to the test result;

(c) according to a predetermined rule and under control of the processing unit, transferring the IC that failed to reach the pass threshold to one of the multiple testing units that conforms to the predetermined rule to conduct a retest operation, wherein the predetermined rule is set based on the pass rates of the multiple testing units; and

(d) assessing whether the IC that failed to reach the pass threshold in step (b) has reached the pass threshold in the retest operation.

The present invention discloses a system-level IC test equipment for testing a plurality of ICs under test, which comprises:

multiple testing units adapted for testing the IC chips independently;

a loading/unloading unit for picking up one of the IC chips and transferring it to a corresponding one of the multiple testing units where the IC chip is subjected to a test operation and taking the IC chip away from the corresponding testing unit after the test operation is finished; and

a processing unit for receiving a test result from the corresponding testing unit and giving a command, according to a predetermined rule, to transfer anyone of the IC chips that failed to reach a pass threshold to one of the multiple testing units that conforms to the predetermined rule to conduct a retest operation.

The automatic retest method for a system-level IC test equipment and the IC test equipment disclosed in the present invention allow IC chips to be automatically tested and automatically retested if required, wherein a predetermined rule can be set and stored in the memory device of the processing unit to serve as a basis of selecting a testing unit for retesting an IC chip. It is possible that the performance of an IC under test is slightly less than a predetermined value due to a certain error occurring in the testing unit. In this case, a testing unit that conforms to the predetermined rule is selected to conduct a retest operation for the IC, thereby achieving a more reasonable and objective test result and avoiding the problem of mistakenly classifying a workable IC as a defect device. In a preferred embodiment, the original testing unit may be excluded from being selected for the retest operation, thereby further reducing the possibility of a misclassification and increasing the efficiency of the retest operation.

### BRIEF DESCRIPTION OF THE DRAWINGS

FIG. 1 shows a system-level IC test equipment according to a first embodiment of the present invention;

FIG. 2 shows a block diagram of the IC test equipment shown in FIG. 2;

FIG. 3 shows a flowchart according to the first embodiment of the present invention, wherein the flowchart illustrates: when an IC chip under test fails to reach the pass threshold, a testing unit will be selected from multiple testing units to conduct a retest operation for the failed IC;

FIG. 4 shows a flowchart according to a second embodiment of the present invention, wherein the original predetermined rule is added with: when an IC chip under test fails to reach the pass threshold, the original testing unit will be immediately selected to conduct a retest operation for the failed IC;

FIG. 5 shows a flowchart according to a third embodiment of the present invention, wherein the flowchart illustrates: when an IC chip under test fails to reach the pass threshold, a testing unit will be selected from the testing units that have reached a predetermined level of pass rate to conduct a retest operation for the failed IC, and the original testing unit will be excluded from conducting a retest operation; and

FIG. 6 shows a modified flowchart according to the third embodiment of the present invention shown in FIG. 5, wherein the original predetermined rule is modified as: when an IC chip under test fails to reach the pass threshold, a testing unit will be selected from the upper half of the testing units that has a greater pass rate to conduct a retest operation for the failed IC.

### DETAILED DESCRIPTION OF THE ILLUSTRATED EMBODIMENTS

The following paragraphs will describe the technical contents, features and effects in detail with various preferred embodiments taken in conjunction with the accompanying drawings, wherein the same or similar elements will be indicated by a similar numeral.

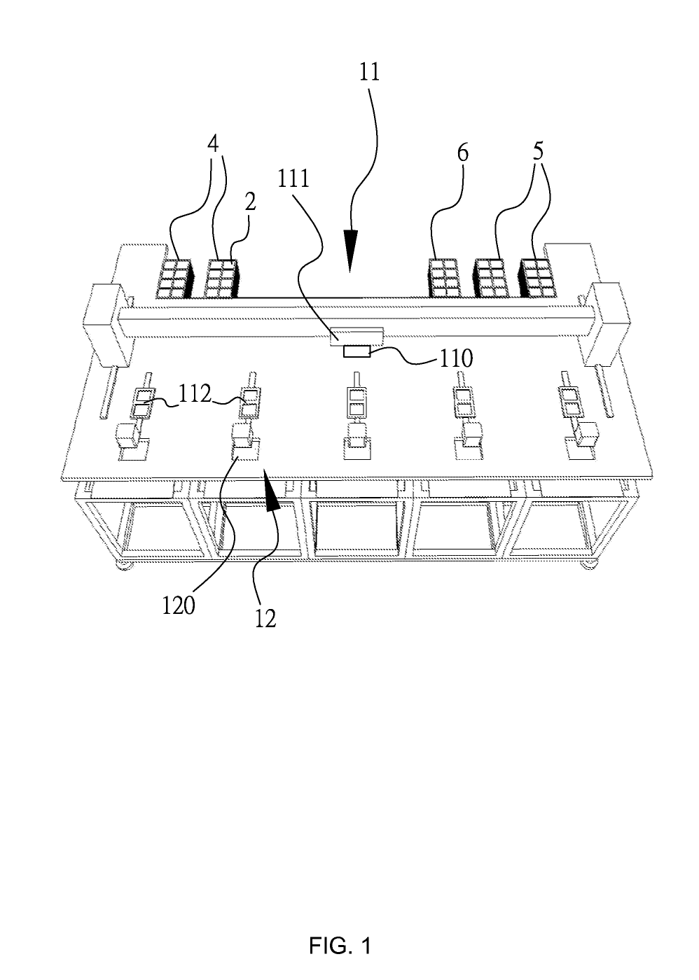

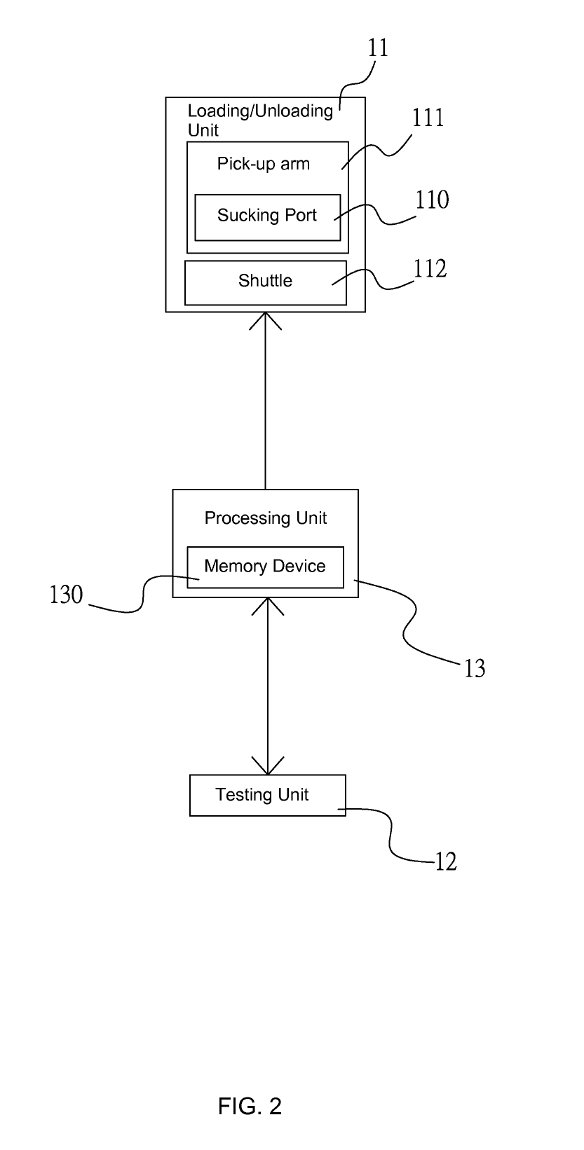

Referring to FIGS. 1 and 2, an automatic retest method for a system-level IC test equipment and the IC test equipment according to a first embodiment of the present invention is shown, wherein the system-level IC test equipment generally comprises a loading/unloading unit 11, multiple testing units 12, and a processing unit 13. In the first embodiment, the testing units 12 are exemplarily shown as test circuit boards in signal communication with the processing unit 13. The loading/unloading unit 11 includes a pick-up arm 111 and multiple shuttles 112, wherein the pick-up arm 111 has a sucking port 110. The processing unit 13 includes a memory device 130.

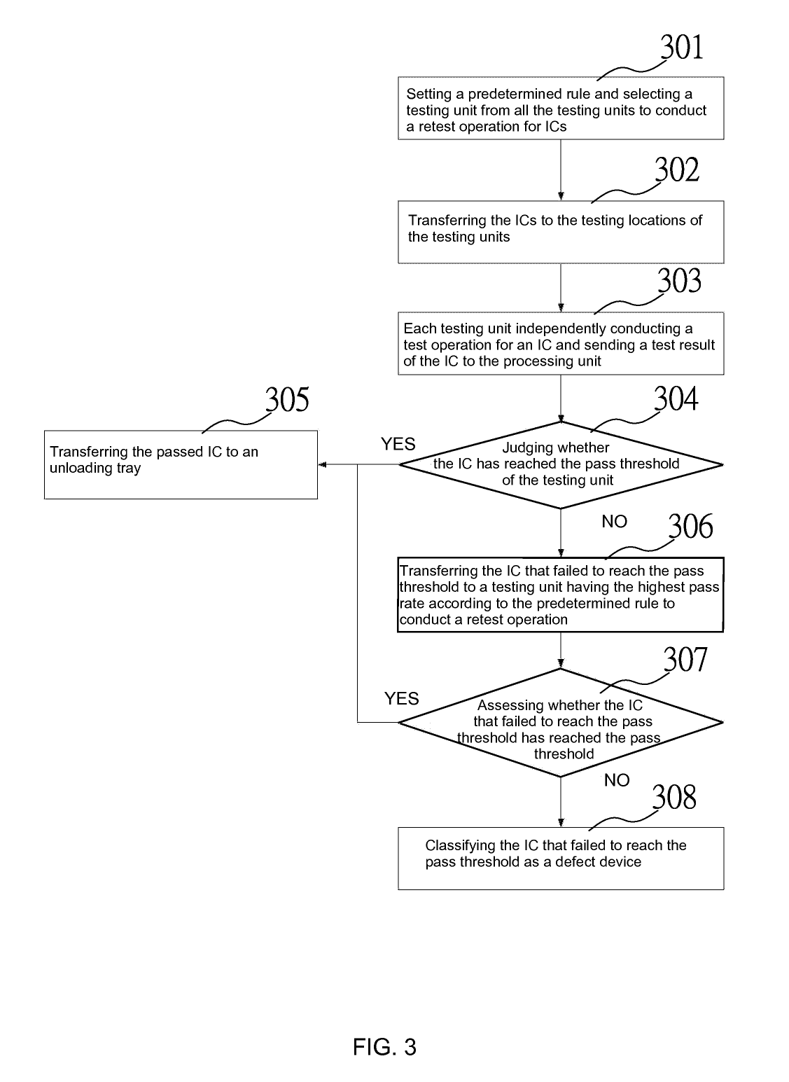

FIG. 3 shows a flowchart according to the first embodiment of the present invention to proceed with an IC test. First, at the step 301, a predetermined rule is set and stored in the memory device 130, wherein the predetermined rule is set to select a testing unit from the multiple testing units 12 to conduct a retest operation for an IC chip 2 failed to reach the pass threshold of the testing unit, wherein the selected testing unit 12 has a highest pass rate among the multiple testing units 12.

Next, at the step 302, the pick-up arm 111 of the loading/unloading unit 11 picks up the IC chips 2 from a loading tray 4 using the sucking port 110 and place onto the shuttles 112 corresponding to the respective testing units 12 for transferring the IC chips 2 to the testing locations of the testing units 12. At the step 303, the testing units 12 independently conduct a test operation for the IC chips 2 positioned at the testing locations associated thereto and transmit a test result of the IC chips to the processing unit 13. In this embodiment, the IC chips 2 are tested for their performance respectively by mounting them on or connecting them to a mounting site 120 of a mother board and then having them execute a predetermined software to perform, for example, a large amount of computation during the test.

Next, at the step 304, the processing unit 13, upon receiving the test result of the IC chips 2, judges whether the respective IC chips have reached the pass threshold of the testing units. If the IC chips 2 have reached the pass threshold, the step 305 will be executed. At the step 305, the corresponding shuttles 112 of the loading/unloading unit 11 transfer the IC chips which pass the test to the pick-up arm 111 through the sucking port 110, and then the pick-up arm 111 delivers the IC chips to an storage tray 5 which is assigned for those that passed the test.

In contrast, if the test result reveals that one of the IC chips 2 failed to reach the pass threshold, then the step 306 is executed. At the step 306, according to the predetermined rule stored in the memory device 130, the failed IC will be transferred to a testing unit that has a highest pass rate, which may be based on a value being accumulated to the date of one day before the testing date, and allow it to conduct a retest operation. Afterwards, the step 307 is executed. At the step 307, the processing unit 13, upon receiving a test result of the IC being retested, judges whether the IC being retested has reached the pass threshold of the testing unit. If the IC being retested has reached the pass threshold, the step 305 is executed, whereby the IC is delivered to the storage tray 5 assigned for those which passed the test. If the IC being retested fails, then the step 308 is executed, whereby the IC which failed in the retest operation is considered defective and delivered by the pick-up arm 111 of the loading/unloading unit 11 to a storage tray 6 assigned for the defect ICs.

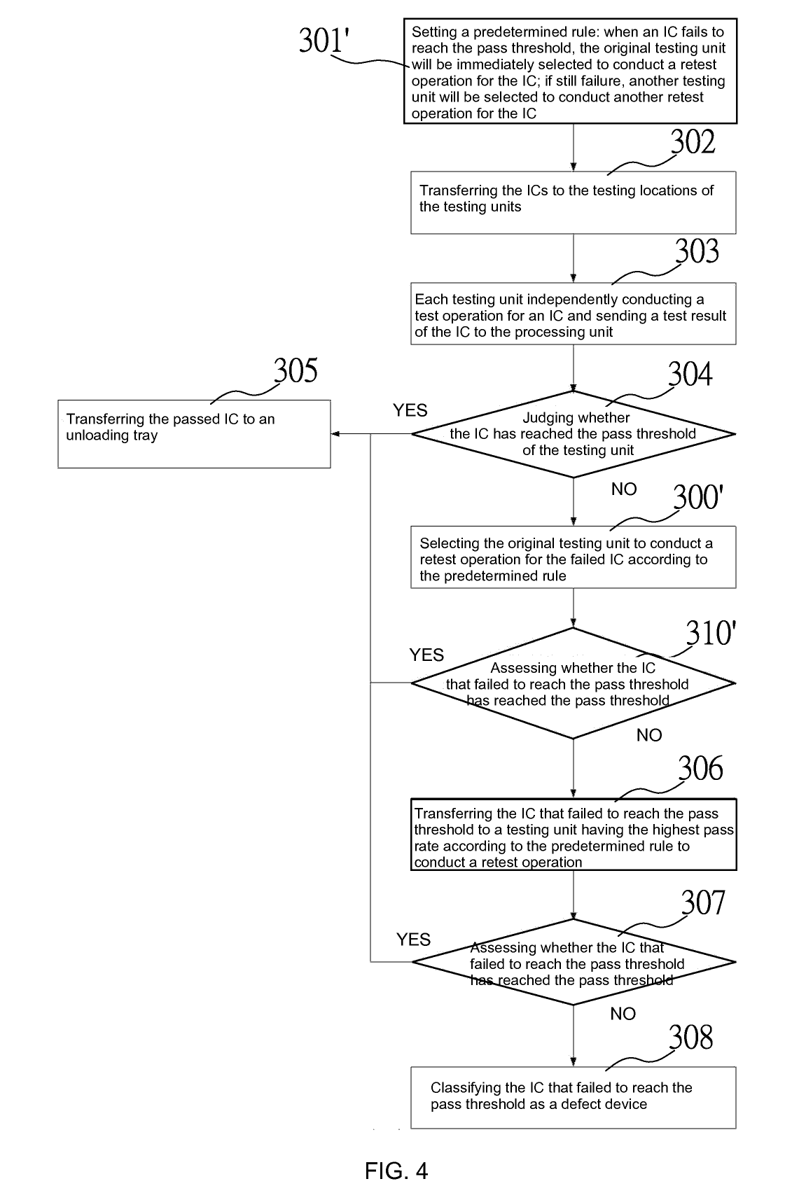

Of course, some IC chips may be required to meet a higher standard, according to which the IC chips will be regarded as qualified devices only when they successfully pass the retest conducted by the original testing units 12. For this reason, the present invention provides a second embodiment, as shown in FIG. 4. In this embodiment, at the step 301′, the predetermined rule stored in the memory device 130 is set to select the testing unit used to inspect an IC chip 2 during the test operation to conduct a retest operation on IC chip 2 when the IC chip 2 failed to reach the pass threshold of the testing unit. If the IC chip still fails in the retest operation, the IC will be regarded as nonconformance with the higher standard. However, the IC can still be classified as a downgrade, or alternatively, another testing unit can be selected to conduct a retest operation again for the IC.

Accordingly, the step 300′ and the step 310′ can be added following the step 304. According to the predetermined rule stored in the memory device 130, the IC which fails in the original test will be retested by the corresponding testing unit that conducted the original test. If the IC passes in the retest operation, the IC will be considered as a workable device, and the step 305 will then be executed, whereby the IC will be delivered to the storage tray 5. If the IC fails in the retest operation, the step 306 will be executed.

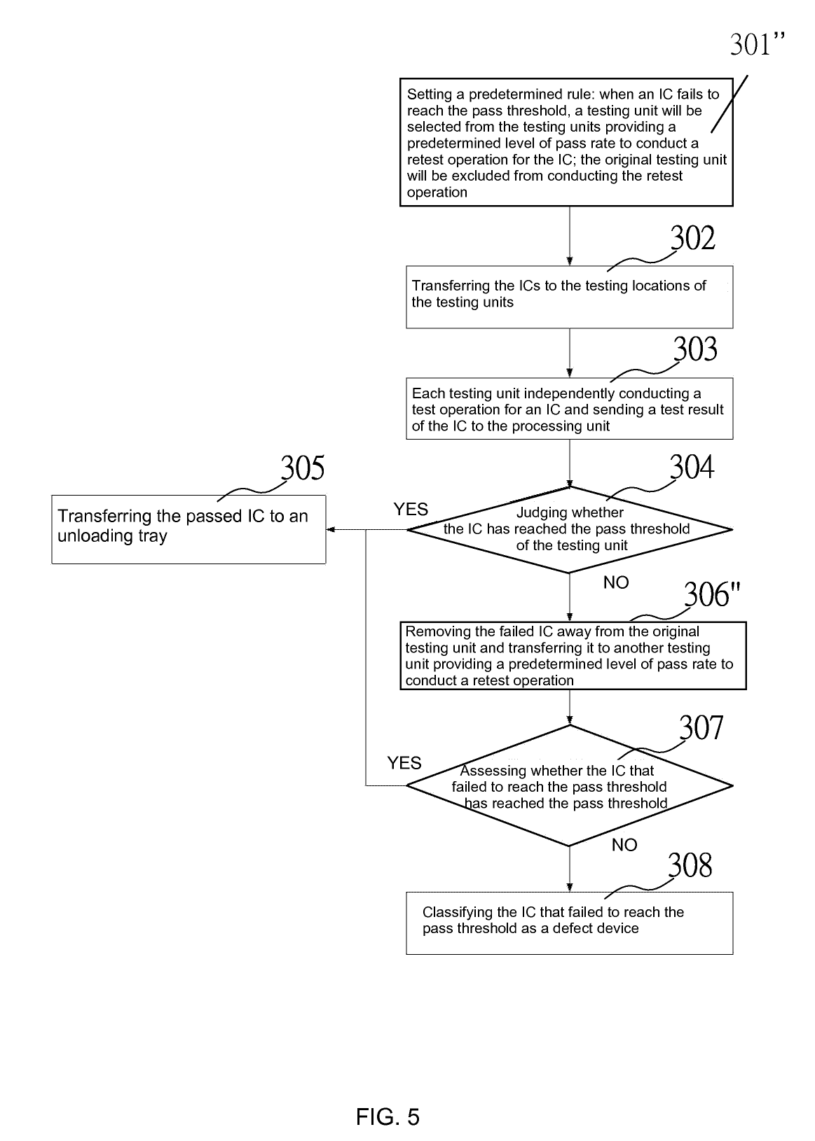

The test approach used in the third embodiment of the present invention is generally the same as the previous embodiments except that the predetermined rule stored in the memory device 130 is changed. Please refer to FIG. 5 taken in conjunction with FIGS. 1 and 2 for a better understanding. At the step 301″, a predetermined rule will be set and stored in the memory device 130, wherein the predetermined rule is set to select one of the testing units that provides a predetermined level of pass rate to conduct a retest operation on an IC chip 2 which has not passed the original test. In this embodiment, for example, the selected testing unit must have an accumulated pass rate of greater than 70% in the past three days. In addition, the predetermined rule can be further limited such that, when the IC chip 2 is to be subjected to retest, the testing unit originally used to conduct the test operation for the IC chip 2 is excluded from being selected for the retest operation. Accordingly, at the step 304, if the IC chip 2 under test fails to reach the pass threshold, the step 306″ will be executed, whereby the failed IC chip is removed away from the current testing unit and transferred to another testing unit, which is selected from the multiple testing units 12 and has a pass rate of greater than 70%, where the IC chip 2 is subjected to retest.

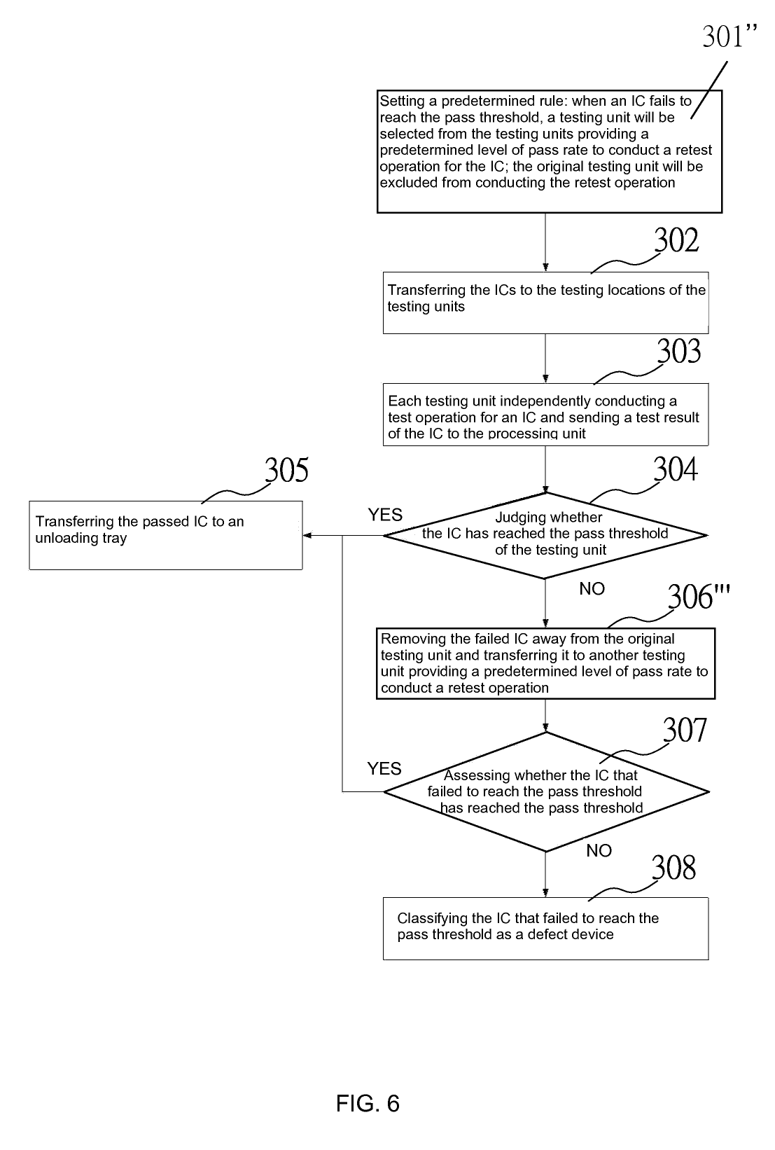

Referring to FIG. 6, a modified flowchart according to the third embodiment of the present invention is provided, which can be understood easily together with FIGS. 1 and 2. At the step 301′″, the predetermined rule is modified to select a testing unit from the upper half of the multiple testing units 12 that have greater pass rates as compared with the lower half of the multiple testing units 12 to conduct retest for an IC chip 2 that failed to pass the original test. In addition, the predetermined rule can be further limited such that, when the IC chip 2 is to be subjected to a retest, the testing unit originally used to conduct the test operation is excluded from being selected for the retest operation. Accordingly, at the step 304, if the IC chip 2 under test fails to reach the pass threshold, the step 306′″ will be executed, whereby the failed IC chip will be removed away from the current testing unit and transferred to another testing unit selected from the upper half of the multiple testing units 12 having greater pass rates, where the IC chip 2 is subjected to retest.

In conclusion, the automatic retest method for use in a system-level IC test equipment and the IC test equipment disclosed herein allow IC chips to be automatically tested and automatically retested when needed, wherein a predetermined rule can be set and stored in the memory device of the processing unit according to an operator's needs. As such, when a retest is required, a testing unit will be selected according to the predetermined rule to avoid the occurrence of errors that tend to happen in traditional testing due to an abnormal condition of a testing unit and often lead to a false-negative performance of the IC chip being tested. With the present invention, an automatic retest can be conducted by a testing unit selected from the multiple testing units in accordance with the predetermined rule to alleviate the problem of misjudging a workable IC as a defect device. In addition, the predetermined rule can be further added with a limitation to exclude the original testing unit from conducting the retest operation to further reduce the possibility of a misjudgment. Alternatively, the original testing unit can be directly selected to conduct a retest operation so that the IC chips passing the test and the retest will meet a high standard. With the present invention, the efficiency of testing IC chips can be increased and the flexibility of retesting IC chips can be enhanced.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit and scope of the invention.

What is claimed is:

1. A method of testing IC chips for a system-level IC test equipment that includes a processing unit, a loading/unloading unit, and multiple testing units adapted for testing the IC chips independently, wherein each of the testing units provides a pass rate for IC chips, the method comprising the steps of:
(a) using the testing units to test the IC chips individually and transmitting a test result of the IC chips to the processing unit;
(b) using the processing unit to assess whether the respective IC chips have reached pass thresholds of the respective testing units, according to the test result;
(c) according to a predetermined rule and under control of the processing unit, transferring the IC that failed to reach the pass threshold to one of the multiple testing units that conforms to the predetermined rule to conduct a retest operation, wherein the predetermined rule is set based on the pass rates of the multiple testing units; and
(d) assessing whether the IC that failed to reach the pass threshold in step (b) has reached the pass threshold in the retest operation.

2. The method of claim 1, further comprising, before the step (a), a step (e) of setting the predetermined rule, wherein the predetermined rule is set to select a testing unit having a highest pass rate from the testing units to conduct the retest operation for the IC which fails to reach the pass threshold in step (b).

3. The method of claim 1, further comprising, before the step (a), a step (f) of setting the predetermined rule, wherein the predetermined rule is set to immediately select the corresponding testing unit originally used for testing the IC which fails to reach the pass threshold in step (b) to conduct the retest operation for the IC in step (c).

4. The method of claim 1, further comprising, before the step (a), a step (g) of setting the predetermined rule, wherein the predetermined rule is set to select a testing unit from the testing units that have reached a predetermined level of pass rate to conduct a retest operation for the IC which fails to reach the pass threshold in step (b).

5. The method of claim 4, wherein the predetermined rule is further set to comprise excluding the corresponding testing unit originally used for testing the IC which fails to reach the pass threshold in step (b) from being selected for the retest operation for the IC in step (c).

6. The method of claim 1, further comprising, before the step (a), a step (h) of setting the predetermined rule, wherein the predetermined rule is set to select a testing unit from the upper half of the multiple testing units that have greater pass rates as compared with the lower half of the multiple testing units to conduct the retest operation for the IC in step (c).

7. The method of claim 6, wherein the predetermined rule is further set to comprise excluding the corresponding testing unit originally used for testing the IC which fails to reach the pass threshold in step (b) from being selected for the retest operation for the IC in step (c).

8. A system-level IC test equipment for testing a plurality of IC chips, comprising:
multiple testing units adapted for testing the IC chips independently;
a loading/unloading unit for picking up one of the IC chips and transferring it to a corresponding one of the multiple testing units where the IC chip is subjected to a test operation and taking the IC chip away from the corresponding testing unit after the test operation is finished; and
a processing unit for receiving a test result from the corresponding testing unit and giving a command, according to a predetermined rule, to transfer anyone of the IC chips that failed to reach a pass threshold to one of the multiple testing units that conforms to the predetermined rule to conduct a retest operation.

9. The system-level IC test equipment of claim 8, wherein the loading/unloading unit comprises multiple shuttles corresponding to the multiple testing units for accommodating the ICs under test.

10. The system-level IC test equipment of claim 8, wherein the processing unit comprises a memory device that stores the predetermined rule.
